(19) United States
(12) Patent Application Publication
(10) Pub. No.: US 2025/0241116 A1
(43) Pub. Date: Jul. 24, 2025

(54) LIGHT EMITTING DEVICE AND LIGHT EMITTING DISPLAY DEVICE INCLUDING THE SAME

(71) Applicant: LG DISPLAY CO., LTD., Seoul (KR)

(72) Inventors: Byung Geol KIM, Paju-si (KR); Seung Hyun KIM, Paju-si (KR); Min Hyeong HWANG, Paju-si (KR); Eun Jung PARK, Paju-si (KR)

(73) Assignee: LG DISPLAY CO., LTD., Seoul (KR)

(21) Appl. No.: 18/989,891

(22) Filed: Dec. 20, 2024

(30) Foreign Application Priority Data
Dec. 29, 2023 (KR) 10-2023-0197872

(51) Int. Cl. H10K 50/12; H10K 50/13; H10K 59/35; H10K 85/60; H10K 101/00; H10K 101/30

(52) U.S. Cl. CPC H10K 50/12; H10K 50/131; H10K 59/351; H10K 85/615; H10K 85/654; H10K 85/6572; H10K 85/6574; H10K 2101/30; H10K 2101/90

(57) ABSTRACT

A light emitting device can include a first electrode and a second electrode facing each other, and an intermediate layer having at least one blue light emitting stack and at least one phosphorescent light emitting stack between the first electrode and the second electrode, the intermediate layer emitting white light. The phosphorescent light emitting stack can include a first phosphorescent light emitting layer, a second phosphorescent light emitting layer, and a third phosphorescent light emitting layer, each emitting light with a longer wavelength than blue light. The third phosphorescent light emitting layer can include a hole-transporting host, an electron-transporting host, an auxiliary exciton-forming host having a LUMO energy level that is 2.4 eV to 2.7 eV different from a HOMO energy level of the hole-transporting host, and a dopant.

### CROSS REFERENCE TO RELATED APPLICATION

This application claims the priority benefit of the Korean Patent Application No. 10-2023-0197872, filed in the Republic of Korea on Dec. 29, 2023, the entire contents of which are hereby incorporated by reference into the present application.

### BACKGROUND

### Field of the Invention

The disclosure relates to a light emitting device, and more particularly, to a light emitting device and a light emitting display device to improve luminous efficacy as well as lifespan.

### Discussion of the Related Art

With the advent of the information society, displays for visually expressing electrical information signals have rapidly developed. In response to this, a variety of display devices with excellent performance such as slimness, low weight, and low power consumption are being developed.

A light emitting display device that does not require a separate light source to realize compactness and clear color and has a light emitting device in a display panel has been considered as a competitive application.

The light emitting device can include an anode and a cathode facing each other as electrodes, a light emitting layer between the two electrodes, and a common layer for transferring holes and electrons to the light emitting layer.

Meanwhile, light emitting devices use light emitting materials that emit light with different wavelengths for expressing color, and can have differences in efficiency and lifespan of the light emitting materials depending on wavelength.

### SUMMARY OF THE DISCLOSURE

Accordingly, the disclosure is directed to a light emitting device and a light emitting display device that substantially obviate one or more problems due to the limitations and disadvantages of the related art.

It is an object of the present disclosure to provide a light emitting device and a light emitting display device that have a modified stack structure including a plurality of phosphorescent light emitting layers to utilize excess excitons in light emission in the phosphorescent light emitting layers, to prevent charge leakage due to imbalance (bias) in light emitting portions and to improve lifespan and efficiency.

Additional advantages, objects, and features of the disclosure will be set forth in part in the description which follows and in part will become apparent to those having ordinary skill in the art upon examination of the following, or can be learned from practice of the disclosure. The objectives and other advantages of the disclosure can be realized and attained by the structure particularly pointed out in the written description and claims hereof as well as the appended drawings.

A light emitting device according to some embodiments of the present disclosure includes a first electrode and a second electrode facing each other, and an intermediate layer having at least one blue light emitting stack and at least one phosphorescent light emitting stack between the first electrode and the second electrode, the intermediate layer emitting white light, wherein the phosphorescent light emitting stack includes a first phosphorescent light emitting layer, a second phosphorescent light emitting layer, and a third phosphorescent light emitting layer, each emitting light with a longer wavelength than blue light, and the third phosphorescent light emitting layer includes a hole-transporting host, an electron-transporting host, an auxiliary exciton-forming host having a lowest unoccupied molecular orbital (LUMO) energy level that is 2.4 eV to 2.7 eV different from a highest occupied molecular orbital (HOMO) energy level of the hole-transporting host, and a dopant.

It is to be understood that both the foregoing general description and the following detailed description of the disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a sectional view illustrating a configuration of a light emitting device according to some embodiments of the present disclosure;

FIG. 2 is an energy band diagram of a phosphorescent light emitting stack of FIG. 1;

FIG. 3 is a diagram illustrating a light emitting area of the phosphorescent light emitting stack;

FIG. 4 is a cross-sectional view illustrating a light emitting device used in the experiment;

FIGS. 5A and 5B are energy band diagrams of phosphorescent light emitting stacks according to Experimental Examples 1 and 2;

FIG. 6 shows energy bands of host materials used in the experiment;

FIG. 7 is a graph showing the PL spectrum of a hole-transporting host GHH and an electron-transporting host GEH;

FIG. 8 is a graph showing the PL spectrum of the hole-transporting host GHH and an auxiliary exciton-forming host NGEH1 of Formula 4;

FIG. 9 is a graph showing the PL spectrum of the hole-transporting host GHH and an auxiliary exciton-forming host NGEH2 of Formula 5;

FIG. 10 is a graph showing the PL spectrum of the hole-transporting host GHH and an auxiliary exciton-forming host NGEH3 of Formula 6;

FIG. 11 is a graph showing the PL spectrum of the hole-transporting host GHH and an auxiliary exciton-forming host NGEH4 of Formula 7;

FIG. 12 is a graph showing an EL white light emitting spectrum of a tandem light emitting device including a phosphorescent light emitting layer of Experimental Example 1;

FIG. 13 is a graph showing an EL white light emitting spectrum of a tandem light emitting device including a phosphorescent light emitting layer of Experimental Example 2;

FIG. 14 is a graph showing an EL white light emitting spectrum of a tandem light emitting device including a phosphorescent light emitting layer of Experimental Example 3; and

FIG. 15 is a cross-sectional view illustrating a light emitting display device according to some embodiments.

### DETAILED DESCRIPTION OF THE EMBODIMENTS

Reference will now be made in detail to embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same can obscure the subject matter of the disclosure. In addition, the names of elements used in the following description are selected in consideration of clarity of description of the disclosure, and can differ from the names of elements of actual products. Further, the term “can” fully encompasses all the meanings and coverages of the term “may.” In addition, all the components of each device according to all embodiments of the present disclosure are operatively coupled and configured.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “LUMO (lowest unoccupied molecular orbital) energy level” and “HOMO (highest occupied molecular orbital) energy level” of a layer refer to the LUMO energy level and HOMO energy level of a material that occupies most of a weight ratio of the layer, for example, a host material, unless the context clearly mentions that the LUMO energy level and the HOMO energy level mean the LUMO energy level and HOMO energy level of a dopant material doped in the layer, respectively.

The HOMO energy level is obtained by measuring the voltage corresponding to a first peak at which electrons are discharged from a target material through cyclic voltammetry (CV) while comparing with a reference material whose HOMO energy level is known. Here, the electron that is first discharged from the material is the outermost electron that is most weakly confined and is in the HOMO energy level.

As used herein, the term “band gap energy (Eg)” is measured with an ultraviolet-visible spectrometer (UV-vis spectrometer).

As used herein, the term “LUMO energy level” is obtained by subtracting the band gap energy from the measured HOMO energy level of the material.

As used herein, the terms “HOMO energy level” and “LUMO energy level” are measured below the vacuum level of 0 eV, and are negative values. Upon comparison of the HOMO energy level and the LUMO energy level between materials, when the HOMO or LUMO energy level of one material is described as being larger or higher than another material, it is plotted at a higher level than the energy band diagram and has a small absolute value, and when the HOMO or LUMO energy level of one material is described as being smaller or lower than another material, it is plotted at a lower level than the energy band diagram and has a larger absolute value.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt. %, or when the p-type material is present in an amount of less than 30 wt. %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

As used herein, a stack refers to a unit structure including a common layer including a hole transport layer and an electron transport layer, and a light emitting layer disposed between the hole transport layer and the electron transport layer, unless it is limited to a specific structure in some embodiments. The common layer can further include a hole injection layer, an electron blocking layer, a hole blocking layer, and an electron injection layer, and can further include other common layers depending on the structure or design of the light emitting device.

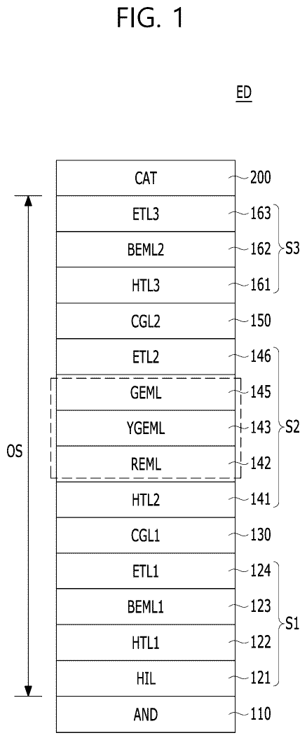

FIG. 1 is a sectional view illustrating a configuration of a light emitting device according to some embodiments of the present disclosure.

As shown in FIG. 1, the light emitting device according to some embodiments of the present disclosure includes a first electrode 110 and a second electrode 200 facing each other, and an intermediate layer OS disposed between the first electrode 110 and the second electrode 200, and including at least one blue light emitting stack S1 or S3 and at least one phosphorescent light emitting stack S2 to emit white light.

One of the first electrode 110 and the second electrode 200 can be an anode AND, and the other can be a cathode CAT. FIG. 1 shows an example where the first electrode 110 is an anode AND and the second electrode 200 is a cathode CAT, but the embodiments of the present disclosure is not limited thereto.

One of the first electrode 110 and the second electrode 200 is connected to the thin film transistor of each subpixel provided on the substrate and the other thereof receives a common voltage from a plurality of subpixels.

One of the first electrode 110 and the second electrode 200 can be a reflective electrode, and the other thereof can be a transparent electrode or a semi-transparent electrode. When the first electrode 110 is a transparent electrode and the second electrode 200 is a reflective electrode, the light emitting device emits light from the bottom. When the first electrode 110 is a reflective electrode and the second electrode 200 is a transparent electrode or a semi-transparent electrode, the light emitting device emits light from the top. In other embodiments of the present disclosure, each of the first electrode 110 and the second electrode 200 is formed as a non-reflective electrode, so that the light emitting device can emit light from both the top and bottom surfaces.

When the first electrode 110 is a transparent electrode, the first electrode 110 can contain indium tin oxide (ITO), IZO (indium zinc oxide), or ITZO (indium tin zinc oxide). When the second electrode 200 is a reflective electrode, the second electrode 200 can contain aluminum (Al), silver (Ag), magnesium (Mg), or an alloy thereof.

At least one of the first and second electrodes 110 and 200 can be formed of a plurality of layers.

The first electrode 110 is connected to the thin film transistor provided on the substrate to selectively receive a signal supplied to each subpixel, and the second electrode 200 is provided in common among the subpixels and receives a common voltage. When the device configuration of FIG. 1 is turned down, the second electrode 200 located in the lower area is connected to a thin film transistor, and the first electrode located in the upper area is provided throughout a plurality of subpixels to receive a common voltage.

An intermediate layer OS is provided between the first and second electrodes 110 and 200, and the light emission characteristics of the light emitting device can be controlled depending on the thickness of the intermediate layer OS and the layers provided in the intermediate layer OS. The intermediate layer OS can include a plurality of organic layers. One or more of the plurality of layers included in the intermediate layer OS can further contain a metal or an inorganic material other than metal. The metal and inorganic material other than metal can be provided singly in one or more of the plurality of layers, or can form a complex with an organic material.

For example, the intermediate layer OS can include a plurality of stacks S1, S2, and S3 to emit white light. As shown, the plurality of stacks S1, S2, and S3 can be provided as three stacks, but the embodiments of the present disclosure is not limited thereto. The stack provided in the intermediate layer OS can include two stacks, or four or more stacks. Charge generation layers CGL1 and CGL2 are provided between the stacks to generate and transfer holes or electrons required for each stack. For example, the charge generation layers CGL1 and CGL2 can include a plurality of layers, including an n-type charge generation layer and a p-type charge generation layer, respectively, containing an n-type dopant and a p-type dopant, but is not limited thereto. The charge generation layer CGL1 or CGL2 can be formed as a single layer, or at least one of the n-type charge generation layer and the p-type charge generation layer can be formed as multiple layers with different contents. In some cases, at least one of the two or more charge generation layers provided in three or more stacks can have a different layer configuration.

The first stack S1 can include a hole injection layer (HIL) 121 that is adjacent to the first electrode 110 and is configured to inject holes from the first electrode 110, and a first hole transport layer (HTL1) 122 configured to transport holes from the hole injection layer (HIL) 121, and a first blue light emitting layer (BEML1) 123, and a first electron transport layer (ETL1) 124.

The second stack S2 includes a second hole transport layer (HTL2) 141, a first phosphorescent light emitting layer 142, a second phosphorescent light emitting layer 143, a third phosphorescent light emitting layer 145, and a second electron transport layer (ETL2) 146.

The third stack S3 can include a third hole transport layer (HTL3) 161, a second blue light emitting layer (BEML2) 162, and a third electron transport layer (ETL3) 163.

In the example shown in FIG. 1, a phosphorescent light emitting stack including a plurality of phosphorescent light emitting layers 142, 143, and 145 is provided as a second stack S2 in the intermediate layer OS, but the embodiments of the present disclosure is not limited thereto. For example, the phosphorescent light emitting stack can contact the first electrode 110 or the second electrode 200.

In addition, the stack emitting blue light can include two stacks S1 and S3, as shown in FIG. 1, or can be provided as a single stack.

When a light emitting device has a high color temperature or expresses high illumination or luminance, it can further include at least one of a blue light emitting stack that emits blue light and a phosphorescent light emitting stack.

When the first and third stacks S1 and S3 are blue light emitting stacks, the blue light emitting layers BEML1 and BEML2 can include, for example, a blue fluorescent material to obtain a desired lifespan. The blue light emitting layers BEML1 and BEML2 can include a blue phosphorescent material or a blue thermally activated delayed fluorescence (TADF) material in addition to the blue fluorescent material. The blue light emitting layer can be divided into multiple layers, depending on the ratio of the light emitting material provided in the blue light emitting layer BEML1 or BEML2, or whether or not a certain material is applied.

As a phosphorescent light emitting stack, the second stack S2 emits light with a longer wavelength than the blue light emitted by the first and third stacks S1 and S3. In the second stack S2, the first to third phosphorescent layers 142, 143, and 145 continuously disposed in one stack each independently use excitons for light emission. Accordingly, the continuously disposed first to third phosphorescent layers 142, 143, and 145 are quenched in a specific light emitting layer when excitons from the adjacent second hole transport layer 141 and the second electron transport layer 146 are biased toward the specific light emitting layer, the extinction can be severe in a certain light emitting light, resulting in a decrease in lifespan. In addition, for example, when excitons are concentrated in the first phosphorescent light emitting layer 142 or the third phosphorescent light emitting layer 145, charges leak to the adjacent second hole transport layer 141 or the second electron transport layer 146, thus causing reduction in lifespan due to charges trapped at the interface with the phosphorescent layers 142 and 145. The light emitting device according to some embodiments of the present disclosure prevents this problem. More specifically, in the phosphorescent light emitting layer with excess supply of holes and electrons, among the continuous phosphorescent light emitting layers, an auxiliary exciton-forming host, other than the dopant, generates additional excitons, and the additionally generated excitons are redistributed to the phosphorescent light emitting layer, thereby contributing to improvement in lifespan and efficiency.

Light emitting layers that emit light having a decreased wavelength away from the first electrode 110 can be disposed in the second stack S2, as the phosphorescent light emitting stack. For example, the first phosphorescent light emitting layer 142 can be a red light emitting layer REML, the second phosphorescent light emitting layer 143 can be a yellow-green light emitting layer YGEML, and the third phosphorescent light emitting layer 145 can be a green light emitting layer GEML.

In addition, the thickness of the first to third phosphorescent layers 142, 143, and 145 included in the phosphorescent light emitting stack can be adjusted to adjust the luminance from the light emitting device.

For example, when the second phosphorescent light emitting layer 143 is thicker than the first and third phosphorescent light emitting layers 142 and 145, it is possible to achieve a luminance of approximately 200 nits. When the target luminance is 200 nits or more, the thickness of the first phosphorescent light emitting layer 142 and the third phosphorescent light emitting layer 145, which emit more pure colors of red and green is designed to be greater than that of the second phosphorescent light emitting layer 143.

When the thickness of any one of the phosphorescent light emitting layers increases, excitons can be concentrated in the thick phosphorescent light emitting layer among the continuous phosphorescent light emitting layers, resulting in extinction, and charge leakage in the common layer adjacent to the thick phosphorescent light emitting layer. Therefore, it is necessary to inhibit these problems.

In particular, when the thickness of the green light emitting layer GEML with the shortest wavelength among the continuous phosphorescent light emitting layers for high brightness is the greatest, charge leakage to the electron transport layer and exciton concentration in the green light emitting layer can occur. For this reason, the light emitting device according to the embodiments of the present disclosure has a structure to solve these problems.

Hereinafter, an example of forming additional excitons in the green light emitting layer GEML as the third phosphorescent light emitting layer 145 will be described.

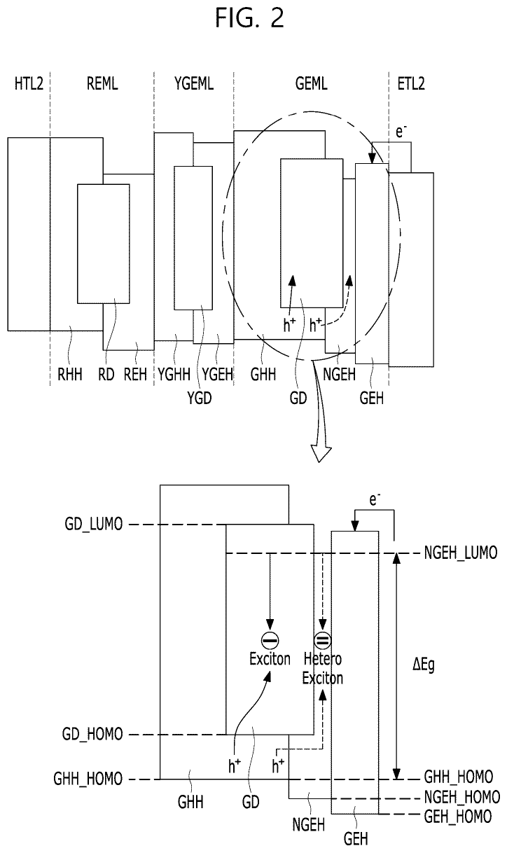

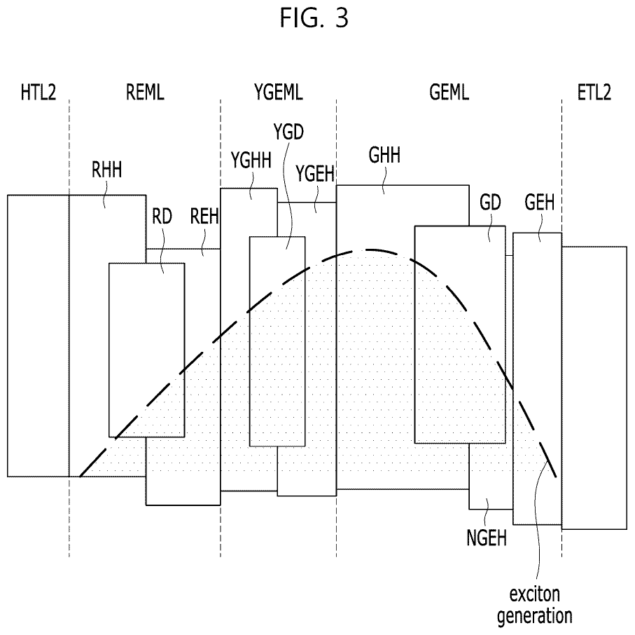

FIG. 2 is an energy band diagram of the phosphorescent light emitting stack of FIG. 1. FIG. 3 shows the light emitting area of the phosphorescent light emitting stack.

As shown in FIGS. 2 and 3, the first phosphorescent light emitting layer REML can include a hole-transporting host RHH, an electron-transporting host REH, and a red dopant RD. Here, the HOMO energy level of the hole-transporting host RHH can be −5.3 eV to −5.6 eV and the LUMO energy level thereof can be −2.2 eV to −2.5 eV. The HOMO energy level of the electron-transporting host REH can be −5.7 eV to −5.9 eV and the LUMO energy level thereof can be −2.8 eV to −3.1 eV. The content of the electron-transporting host REH is greater than the content of the hole-transporting host RHH in the first phosphorescent light emitting layer REML. For example, a content ratio of the hole-transporting host RHH to the electron-transporting host REH can be 3:7 to 4:6.

The second phosphorescent light emitting layer YGEML can include a hole-transporting host YGHH, an electron-transporting host YGEH, and a yellow-green dopant YGD. Here, the HOMO energy level of the hole-transporting host YGHH can be −5.5 eV to −5.8 eV and the LUMO energy level thereof can be −2.3 eV to −2.6 eV. The HOMO energy level of the electron-transporting host YGEH can be −5.7 eV to −5.9 eV and the LUMO energy level thereof can be −2.4 eV to −2.7 eV. For example, the content ratio of the hole-transporting host YGHH to the electron-transporting host YGEH can be 5:5 to 6:4.

The third phosphorescent light emitting layer GEML can include a hole-transporting host GHH, an electron-transporting host GEH, an auxiliary exciton-forming host NGEH, and a green dopant GD. Here, the HOMO energy level of the hole-transporting host GHH can be −5.5 eV to −5.8 eV and the LUMO energy level thereof can be −2.3 eV to −2.6 eV. The HOMO energy level of the electron-transporting host GEH can be −5.8 eV to −6.2 eV and the LUMO energy level thereof can be −2.4 eV to −2.75 eV. In addition, the HOMO energy level of the auxiliary exciton-forming host NGEH can be −5.65 eV to −6.05 eV and the LUMO energy level thereof can be −2.7 eV to −3.15 eV. For example, the ratio of a content of the hole-transporting host GHH to a total content (GEH+NEH) of the electron-transporting host GEH and the auxiliary exciton-forming host NGEH can be 6:4 to 9:1.

Here, the auxiliary exciton-forming host NGEH can be a material with higher electron mobility than the hole-transporting host GHH. For example, the auxiliary exciton-forming host NGEH can have electron transport property in the third phosphorescent light emitting layer GEML. In addition, the auxiliary exciton-forming host NGEH can have hole transport property as well as electron transport property. For this purpose, the auxiliary exciton-forming host NGEH can have an amphipathic molecular configuration.

In addition, the auxiliary exciton-forming host NGEH is capable of forming a hetero-exciton independently of the green dopant GD, and has a LUMO energy level (NEGH_LUMO) which is 2.4 eV to 2.7 eV higher than HOMO energy level (GHH_HOMO) than the hole-transporting host GHH. The energy difference (ΔE) between the HOMO energy level (GHH_HOMO) of the hole-transporting host GHH and the LUMO energy level (NGEH_LUMO) of the auxiliary exciton-forming host NGEH is determined to allow the auxiliary exciton-forming host NGEH to form and accept excitons.

The holes (h⁺) transferred to the hole-transporting host GHH in the third phosphorescent light emitting layer GEML are transferred to the HOMO energy level of the green dopant GD (GD_HOMO) and the HOMO energy level of the auxiliary exciton-forming host NGEH (NGEH_HOMO). The electrons transferred from the adjacent electron transport layer ETL to the third phosphorescent light emitting layer GEML are transferred to the LUMO energy level (GEH_LUMO) of the electron-transporting host GEH and the LUMO energy level (NGEH_LUMO) of the auxiliary exciton-forming host NGEH.

The green dopant GD receives holes (h⁺) from the hole-transporting host GHH and electrons (e) from the electron-transporting host GEH, to form excitons through recombination of the holes with the electrons. When the energy of the exciton falls from the excited state to the ground state, light is emitted.

In the third phosphorescent light emitting layer GEML, the green dopant GD is preferably present in an amount of approximately 1 wt. % to 20 wt. % with respect to a total content of the hole-transporting host GHH, the electron-transporting host GEH, and the auxiliary exciton-forming host NGEH. Typically, the green dopant GD is present in a small amount, ranging from 1 wt. % to 10 wt. %. In this case, when the generation of excitons is concentrated in the green dopant GD present in a small amount in the third phosphorescent light emitting layer GEML, excitons not used for light emission are generated, which can cause extinction and consequent reduction in lifespan.

The light emitting device according to some embodiments of the present disclosure further includes an auxiliary exciton-forming host NGEH in the third phosphorescent light emitting layer GEML, thus forming a hetero-exciton formation region in addition to the green dopant GD, and distributing the excitons in the phosphorescent light emitting layer GEML. The additionally formed excitons can be used for light emission in the third phosphorescent light emitting layer GEML to simultaneously improve efficiency and lifespan. The band gap energy (NGEH_LUMO-NGEH_HOMO) of the auxiliary exciton-forming host NGEH is designed to facilitate the supply of holes and electrons from the hole-transporting host GHH and the electron-transporting host GEH.

The auxiliary exciton-forming host NGEH receives electrons through the LUMO energy level (NGEH_LUMO) thereof adjacent to the LUMO energy level (GD_LUMO) of the green dopant GD, and receives holes through the HOMO energy level (NGEH_HOMO) thereof adjacent to the HOMO energy level (GD_HOMO) of the green dopant GD, thus serving as a hetero-exciton-forming region in addition to the green dopant GD. The excitons formed by the auxiliary exciton-forming host NGEH can be redistributed and moved to the adjacent green dopant GD and then used for light emission.

The LUMO energy level (NGEH_LUMO) of the auxiliary exciton-forming host NGEH can be equal to or smaller than the LUMO energy level (GEH_LUMO) of the electron-transporting host GEH (NGEH_LUMOSGEH_LUMO).

The content of the hole-transporting host GHH in the third phosphorescent light emitting layer GEML can be greater than a total content of the electron-transporting host GEH and the auxiliary exciton-forming host NGEH (content of GHH>content of (GEH+NGEH)). This aims at rapidly supplying holes into the third phosphorescent light emitting layer GEML in response to the rapid supply of electrons from the electron transport layer ETL in contact with the third phosphorescent light emitting layer GEML. The third phosphorescent light emitting layer GEML, which is far from the hole transport layer HTL in the structure of the continuous phosphorescent light emitting layer, contains a great amount of the hole-transporting host GHH, thereby balancing the rate of recombination between the holes and electrons.

The contents of the electron-transporting host GEH and the auxiliary exciton-forming host NGEH in the third phosphorescent light emitting layer GEML can be approximately same or the same. For example, the ratio of the contents of the electron-transporting host GEH and the auxiliary exciton-forming host NGEH may be 4.5:5.5 to 5.5:4.5, preferably 5:5. The auxiliary exciton-forming host NGEH generates excitons and serves as an electron-transporting host to transfer the generated electrons and excitons to the dopant GD.

The HOMO energy level (NGEH_HOMO) of the auxiliary exciton-forming host NGEH can be lower than the HOMO energy level (GHH_HOMO) of the hole-transporting host (NGEH HOMO<GHH_HOMO), the LUMO energy level (NGEH_LUMO) of the auxiliary exciton-forming host can be lower than the HOMO energy level (GHH_HOMO) of the auxiliary exciton-forming host (NGEH_LUMO) (NGEH_LUMO<GHH_LUMO), and the band gap energy (NEGH_LUMO-NEGH HOMO) of the auxiliary exciton-forming host NGEH can be lower than the band gap energy of the hole-transporting host (GHH LUMO-GHH HOMO).

As shown in FIGS. 2 and 3, when, in the phosphorescent light emitting stack, the third phosphorescent light emitting layer GEML emitting green light is the thickest and the second phosphorescent light emitting layer YGEML emitting yellow-green light is the thinnest (thickness: GEML>REML>YGEML), as shown in FIG. 3, formation of excitons can be concentrated in the third phosphorescent light emitting layer GEML. The light emitting device according to some embodiments of the present disclosure generates excitons by the dopant in the thick third phosphorescent light emitting layer GEML, and generates excitons by the auxiliary exciton-forming host NGEH, distributing excitons to prevent extinction, and improving luminous efficacy as well as lifespan sequentially using excitons emitted from the phosphorescent light emitting layers for light emission.

For example, when the third phosphorescent light emitting layer GEML is the thickest, the thickness can be 250 Å to 350 Å. In this case, the thickness of the adjacent second phosphorescent light emitting layer YGEML can be 80 Å to 120 Å. The thickness of the first phosphorescent light emitting layer REML can be 100 Å to 200 Å.

Meanwhile, the hole-transporting host, the electron-transporting host, and the auxiliary exciton-forming host NGEH can be present at a predetermined content ratio in the third phosphorescent light emitting layer GEML. For example, the third phosphorescent light emitting layer GEML can be formed by depositing a mixture of the hole-transporting host GHH, the electron-transporting host GEH, and the auxiliary exciton-forming host NGEH, or depositing these hosts along with a green dopant supplied from a separate deposition source.

Here, the auxiliary exciton-forming host NGEH can generate and accommodate excitons within the energy band gap thereof, thus preventing the excitons generated in the third phosphorescent light emitting layer GEML from leaking to the adjacent electron transport layer, although the third phosphorescent light emitting layer GEML is thick, and thus improving the interface stabilization and reliability of the light emitting device.

The green dopant GD present in the third phosphorescent light emitting layer GEML can be, for example, an iridium complex, for example, a material represented by Formula 1.

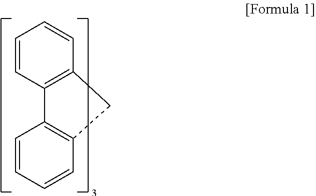

For example, the hole-transporting host GHH of the third phosphorescent light emitting layer GEML can contain bicarbazole as a core and biphenyl as a linker. The hole-transporting host GHH can include hydrogen or deuterium substitution of one or more of linkers in the core. For example, the hole-transporting host GHH can contain a material represented by Formula 2.

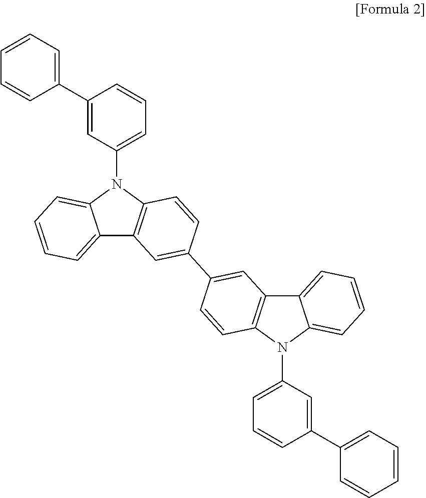 [SMILES: c1ccc(-c2cccc(-n3c4ccccc4c4cc(-c5ccc6c(c5)c5ccccc5n6-c5cccc(-c6ccccc6)c5)ccc43)c2)cc1]

The electron-transporting host GEH of the third phosphorescent light emitting layer GEML can have a bipolar molecular structure to increase the band gap energy. For example, the electron-transporting host GEH can contain dibenzofuran and triphenylene that have high hole transport property, and triazine that has high electron transport property, as shown in Formula 3.

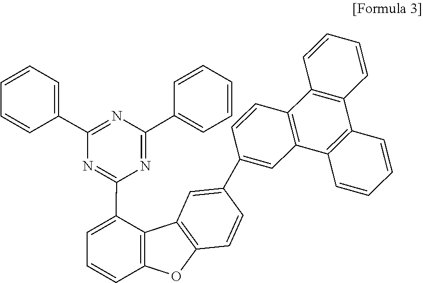 [SMILES: c1ccc(-c2nc(-c3ccccc3)nc(-c3cccc4oc5ccc(-c6ccc7c8ccccc8c8ccccc8c7c6)cc5c34)n2)cc1]

The auxiliary exciton-forming host NGEH is a material capable of transporting electrons well and can contain, for example, a material represented by the following Formulas 4 to 7.

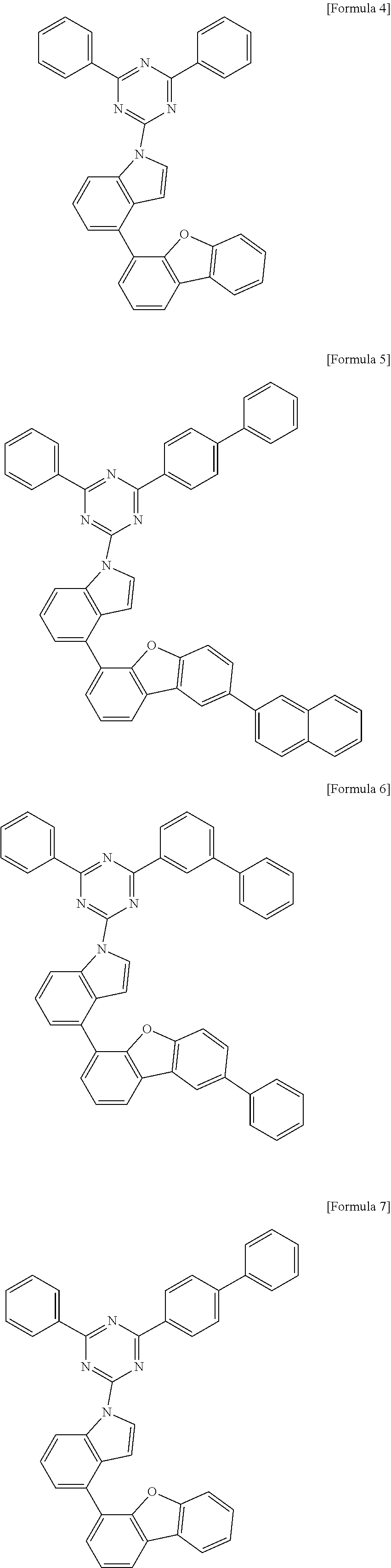 [SMILES: c1ccc(-c2nc(-c3ccccc3)nc(-n3ccc4c(-c5cccc6c5oc5ccccc56)cccc43)n2)cc1 ; c1ccc(-c2ccc(-c3nc(-c4ccccc4)nc(-n4ccc5c(-c6cccc7c6oc6ccc(-c8ccc9ccccc9c8)cc67)cccc54)n3)cc2)cc1 ; c1ccc(-c2cccc(-c3nc(-c4ccccc4)nc(-n4ccc5c(-c6cccc7c6oc6ccc(-c8ccccc8)cc67)cccc54)n3)c2)cc1 ; c1ccc(-c2ccc(-c3nc(-c4ccccc4)nc(-n4ccc5c(-c6cccc7c6oc6ccccc67)cccc54)n3)cc2)cc1]

Hereinafter, the advantages of a structure including an auxiliary exciton-forming host in a phosphorescent light emitting stack including a plurality of phosphorescent light emitting layers will be determined by the following experiments. Hereinafter, the structure of a light emitting device including a phosphorescent light emitting stack as a single stack will be first described and the effects of a tandem light emitting device of FIG. 1 will be evaluated.

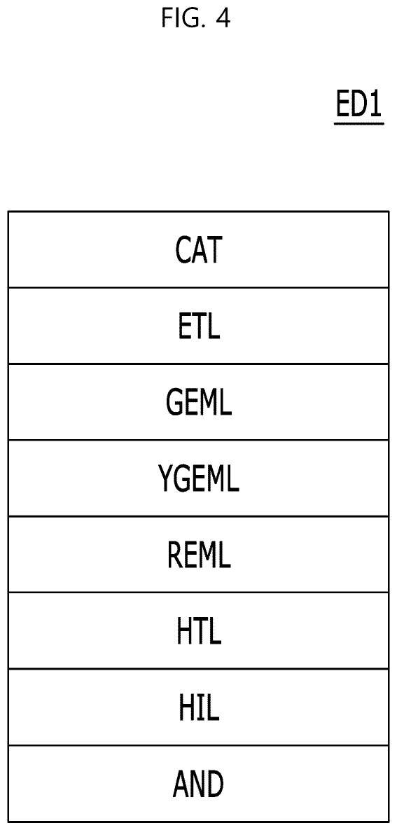

FIG. 4 is a cross-sectional view illustrating a light emitting device used in the experiment.

Referring to FIG. 4, a light emitting device including a single phosphorescent light emitting stack according to Experimental Example 1 (EX1) is formed in the following process.

ITO is deposited to a thickness of 1,200 Å on a substrate to form a first electrode AND.

Then, a hole injection material such as a material of Formula 8 is deposited to a thickness of 100 Å on the first electrode AND to form a hole injection layer HIL.

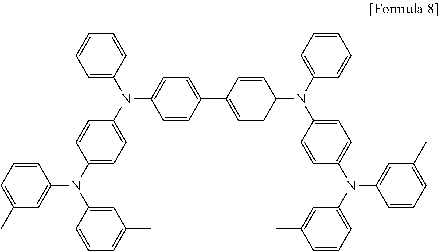 [SMILES: Cc1cccc(N(c2ccc(N(c3ccccc3)c3ccc(C4=CCC(N(c5ccccc5)c5ccc(N(c6cccc(C)c6)c6cccc(C)c6)cc5)C=C4)cc3)cc2)c2cccc(C)c2)c1]

Next, a biphenylamine-based material such as a material of Formula 9 is deposited to a thickness of 80 Å on the hole injection layer (HIL) to form a hole transport layer HTL.

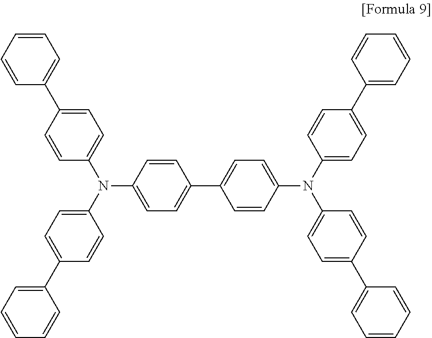 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

Next, a host mixture of the material of Formula 9 as a hole-transporting host RHH and a material of Formula 10 as an electron-transporting host REH is doped with 2 wt. % of a material of Formula 11 as a red dopant to form a red light emitting layer REML. Here, the red light emitting layer REML is formed to a thickness of 150 Å at a content ratio of the hole-transporting host RHH to the electron-transporting host REH of 4:6.

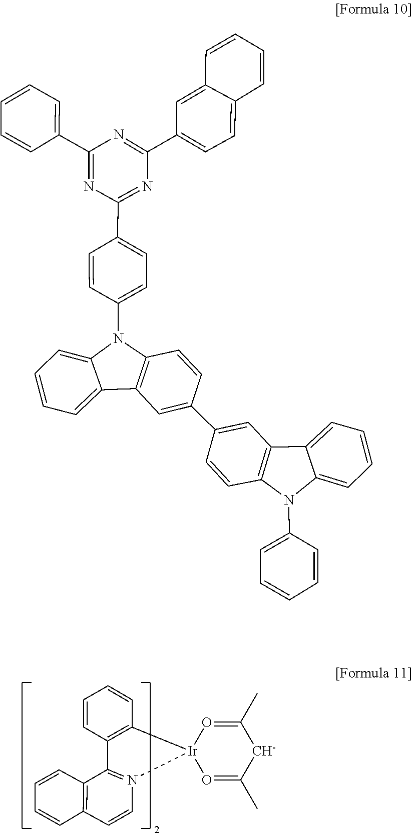

Next, a material of Formula 12 as a hole-transporting host YGHH, and a material of Formula 13 as an electron-transporting host YGEH, are doped with a yellow-green dopant of Formula 14 at 20 wt. % to form a yellow-green light emitting layer YGEML. Here, the yellow-green light emitting layer YGEML is formed to a thickness of 100 Å at a content ratio of the hole-transporting host YGHH to the electron-transporting host YGEH of 5:5.

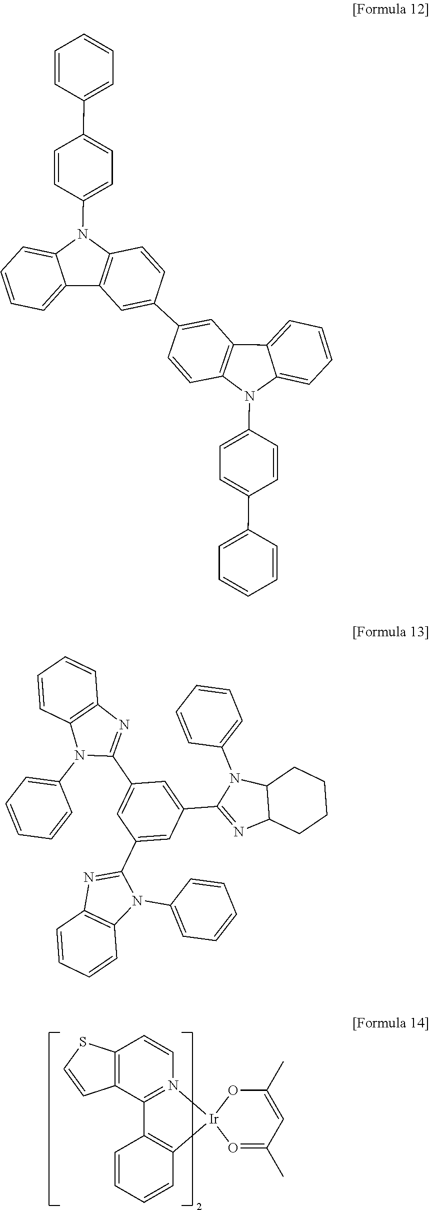

Next, the material of Formula 2 as a hole-transporting host GHH, and the material of Formula 3 as an electron-transporting host GEH are doped with the material of Formula 1 as a green dopant GD at 7 wt. % to form a green light emitting layer GEML. Here, the green light emitting layer GEML is formed to a thickness of 100 Å at a content ratio of the hole-transporting host GHH to the electron-transporting host GEH of 7:3.

Next, a benzimidazole-based material such as a material of Formula 14 is deposited to a thickness of 220 Å to form an electron transport layer ETL.

Next, a material of Formula 15 is deposited to a thickness of 200 Å to form an electron injection layer EIL.

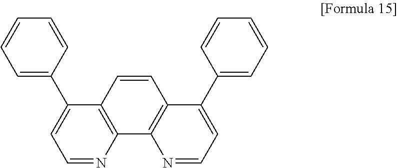 [SMILES: c1ccc(-c2ccnc3c2ccc2c(-c4ccccc4)ccnc23)cc1]

Next, aluminum is deposited on the electron injection layer EIL to form a second electrode CAT.

Experimental Examples 2 to 6 (EX2, EX3, EX4, EX5, EX6) are configured using different electron-transporting hosts to form the green light emitting layer GEML, but using the same hole-transporting host GHH in the green light emitting layer GEML, the same green dopant, the same content and the same configuration of the remaining layers.

For example, in Experimental Example 2 (EX2), the green light emitting layer GEML is formed by doping the material of Formula 2 as the hole-transporting host GHH, and the material of Formula 4 as the electron-transporting host GEH at 7 wt. % with the material of Formula 1. The green light emitting layer GEML is formed to a thickness of 100 Å at a content ratio of the hole-transporting host GHH to the electron-transporting host GEH1 of 7:3.

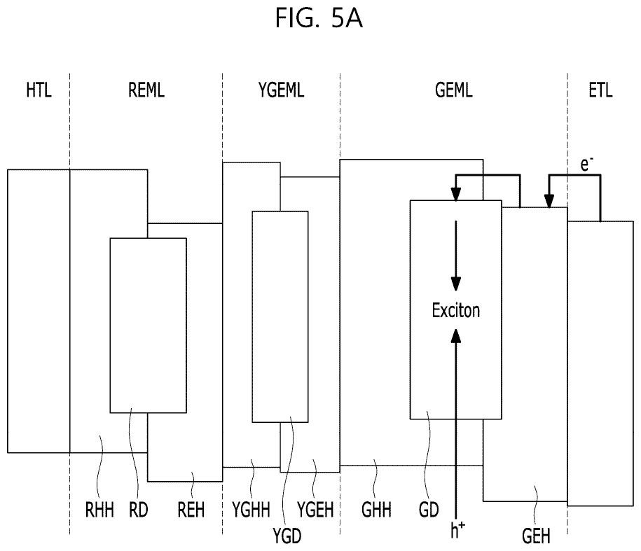

FIGS. 5A and 5B are energy band diagrams of phosphorescent light emitting stacks according to Experimental Examples 1 and 2.

As shown in FIG. 5A, in Experimental Example 1 (EX1), electrons are transferred to the green dopant GD through the electron-transporting host GEH and holes are transferred to the green dopant GD through the hole-transporting host GHH. As a result, formation of the excitons is concentrated in the green dopant GD.

On the other hand, as shown in FIG. 5B, in Experimental Example 2 (EX2), the material of Formula 4 NGEH1 has a band gap energy capable of forming hetero-excitons, thus moving holes and electrons to the material of Formula 4 NGEH1, and making the amount of transfer of holes and electrons required for the green dopant GD insufficient. In addition, electrons not used in the green light emitting layer GEML are biased toward the red light emitting layer REML through the yellow-green light emitting layer YGEML, resulting in the decrease in overall lifespan of the red light emitting layer REML, the yellow-green light emitting layer YGEML, and the green light emitting layer GEML.

In Experimental Example 3 (EX3), the green light emitting layer GEML is formed by doping a mixed host of the material of Formula 2 as a hole-transporting host GHH, the material of Formula 3 as the electron-transporting host GEH, and the material of Formula 4 as an auxiliary exciton-forming host NGEH1 at 7 wt. % with the material of Formula 1 as the green dopant GD. The green light emitting layer GEML is formed to a thickness of 100 Å at a content ratio of the hole-transporting host GHH to the electron-transporting host GEH1 to the auxiliary exciton-forming host NGEH1 of 7:1.5:1.5.

Experimental Example 4 (EX4), Experimental Example 5 (EX5), and Experimental Example 6 (EX6), as the auxiliary exciton-forming host NGEH, include Formula 5, Formula 6, and Formula 7, respectively, and include the same remaining configurations as in Experimental Example 3 (EX3).

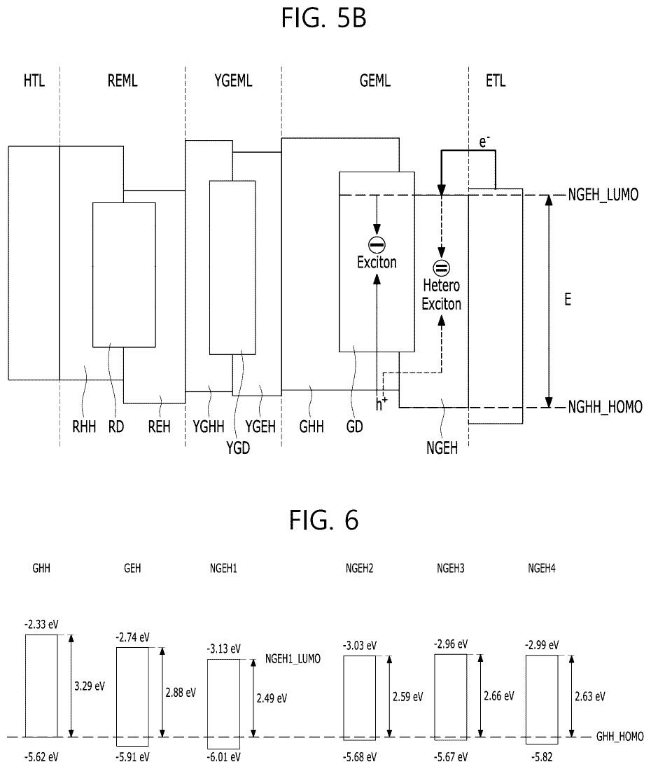

FIG. 6 showings the bandgap energies of host materials used in the experiment.

As shown in FIG. 6, the HOMO energy level of the hole-transporting host GHH is −5.62 eV and the LUMO energy level thereof is −2.33 eV. The HOMO energy level of the electron-transporting host GEH is −5.91 eV and the LUMO energy level thereof is −2.74 eV.

The hole-transporting host GHH has the largest bandgap energy of 3.29 eV among the materials contained in the green light emitting layer GEML. The green light emitting layer (third phosphorescent light emitting layer) of the present disclosure receives holes from the hole-transporting host GHH and thus has a difference between the HOMO energy level of the hole-transporting host GHH and the LUMO energy level of the green light emitting layer, within a predetermined range enabling exciton formation. This difference is smaller than 2.88 eV which is the difference between the LUMO energy level of the electron-transporting host GEH and the HOMO energy level of the hole-transporting host GHH, so that the formation of excitons other than the dopant is possible in the auxiliary exciton-forming host NGEH1.

Experimental Examples 3 to 6 (EX3, EX4, EX5, and EX6) include auxiliary exciton-forming hosts NGEH1, NGEH2, NGEH3, and NGEH4, and the differences between the HOMO energy level of the hole-transporting host GHH and the LUMO energy levels of auxiliary exciton-forming hosts NGEH1, NGEH2, NGEH3, and NGEH4, are higher than 2.49 eV, 2.59 eV, 2.66 eV, and 2.63 eV, respectively. The NGEH1, NGEH2, NGEH3, and NGEH4 materials correspond to Formulas 4 to 7, respectively.

Table 1 shows comparison of Experimental Example 2 (EX2) to Experimental Example 6 (EX6) based on the efficiency, red, yellow-green, and green lifespan (T95) and driving voltage of Experimental Example 1 (EX1). T95 lifespan refers to the time it takes for luminance to reach 95% of the initial 100% luminance, and the efficiency, lifespan (T95), and voltage in Table 1 are measured on the light emitting device at a current density of 100 mA/cm².

TABLE 1

| | | Efficiency | Lifespan (T95)(%) | | | Voltage [V] |
|---|---|---|---|---|---|---|
| Item | Structure | (%) | R | YG | G | @100 mA/cm2 |
| EX1 | GHH:GEH + GD | 100 | 100 | 100 | 100 | 0 |
| EX2 | GHH:NGEH1 + GD | 96 | 54 | 67 | 92 | −0.03 |
| EX3 | GHH:NGEH1:GEH + GD | 96 | 91 | 108 | 135 | +0.06 |
| EX4 | GHH:NGEH2:GEH + GD | 98 | 105 | 122 | 118 | +0.12 |
| EX5 | GHH:NGEH3:GEH + GD | 97 | 77 | 100 | 110 | +0.03 |
| EX6 | GHH:NGEH4:GEH + GD | 99 | 100 | 94 | 103 | +0.34 |

As shown in Table 1, regarding the electroluminescence characteristics of Experimental Example 2 (EX2), when a single auxiliary exciton-forming host NGEH1 is used instead of the electron-transporting host GEH in the green light emitting layer, the holes required for the dopant leak to the auxiliary exciton-forming host, and charges including excitons are rather biased towards the red light emitting layer. As a result, Experimental Example 2 (EX2) exhibit shorter red lifespan, yellow-green lifespan, and green lifespan than Experimental Example 1 (EX1).

As in Experimental Examples 3 to 6 (EX3, EX4, EX5, and EX6), when auxiliary exciton-forming hosts NGEH1, NGEH2, NGEH3, and NGEH4 are used along with the electron-transporting host GEH, the excitons distributed in the green light emitting layer are used for the green light emitting layer and are redistributed to the yellow-green light emitting layer and the red light emitting layer, so the lifespan of green light is remarkably improved and the lifespan of red and yellow-green light is also improved.

Hereinafter, a hole-transporting host GHH is sequentially formed to 100 Å on the glass substrate, and then an electron-transporting host GEH or an auxiliary exciton-forming host NGEH1, NGEH2, NGEH3, or NGEH4 is formed to 100 Å. Whether or not exciplexes are generated during deposition of a mixture of the hosts is determined, compared to the PL spectrum of each layer.

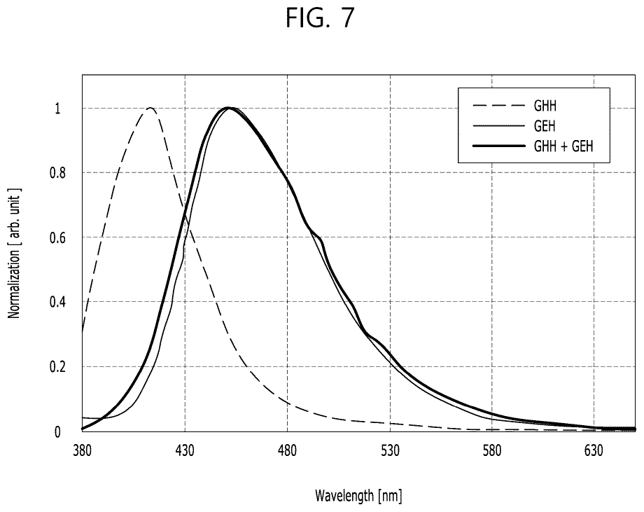

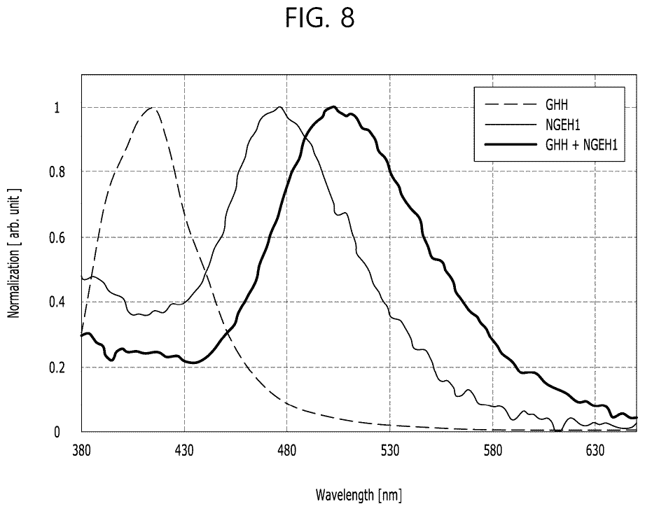

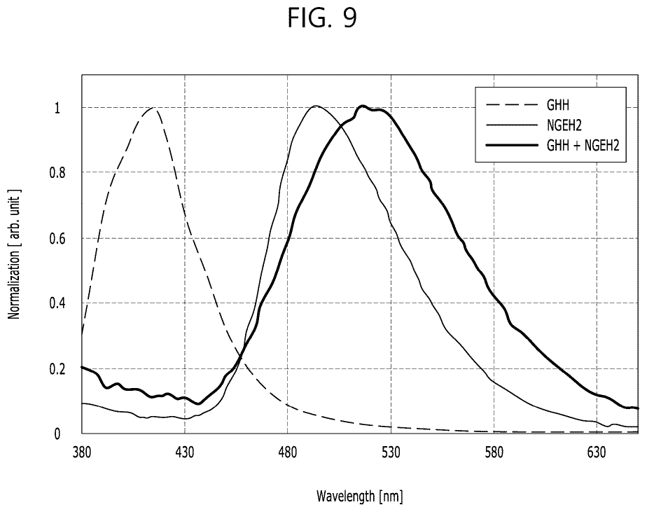

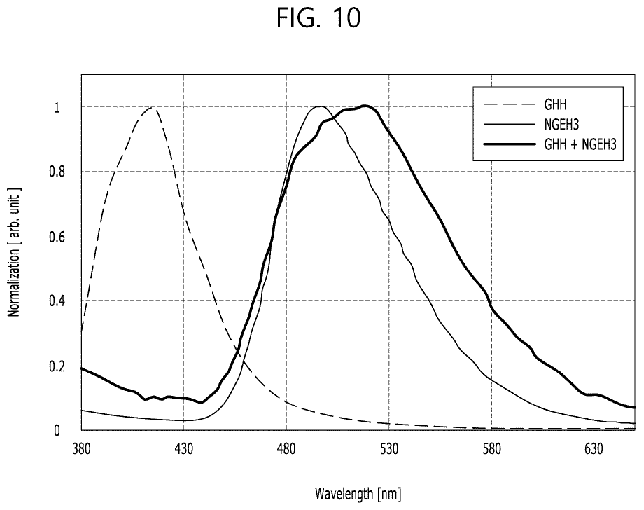

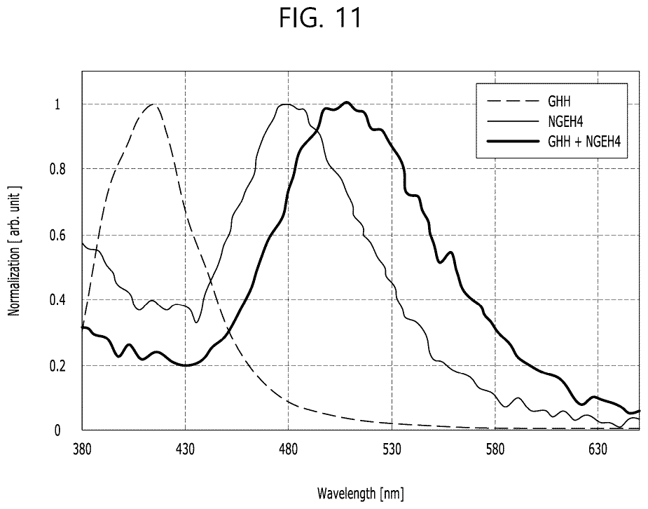

FIG. 7 is a graph showing the PL spectrum of a hole-transporting host GHH and an electron-transporting host GEH. FIG. 8 is a graph showing the PL spectrum of the hole-transporting host GHH and an auxiliary exciton-forming host NGEH1 of Formula 4. FIG. 9 is a graph showing the PL spectrum of the hole-transporting host GHH and an auxiliary exciton-forming host NGEH2 of Formula 5. FIG. 10 is a graph showing the PL spectrum of the hole-transporting host GHH and an auxiliary exciton-forming host NGEH3 of Formula 6. FIG. 11 is a graph showing the PL spectrum of the hole-transporting host GHH and the auxiliary exciton-forming host NGEH4 of Formula 7.

As shown in FIG. 7, when a mixture of the hole-transporting host (Formula 2-GHH) and the electron-transporting host (Formula 3-GEH) is deposited, the PL spectrum corresponds to the electron-transporting host GEH, thus avoiding formation of exciplexes.

On the other hand, as shown in FIGS. 8 to 11, a mixture of a hole-transporting host (Formula 2-GHH) and an auxiliary exciton-forming host (Formula 4-NGEH1) (Formula 5-NGEH2) (Formula 6-NGEH3), or (Formula 7-NGEH4) is deposited, the spectrum of each electron-transporting host is shifted to the right, resulting in a PL spectrum with an emission peak of approximately 500 nm to 520 nm. In other words, it can be seen that light emission further occurs within the phosphorescent light emitting layer when the auxiliary exciton-forming host is provided.

EL spectrum of a tandem white light emitting device of FIG. 1 using different host materials of the green light emitting layer GEML of Experimental Example 1 (EX1), Experimental Example 2 (EX2), and Experimental Example 3 (EX3) will be described.

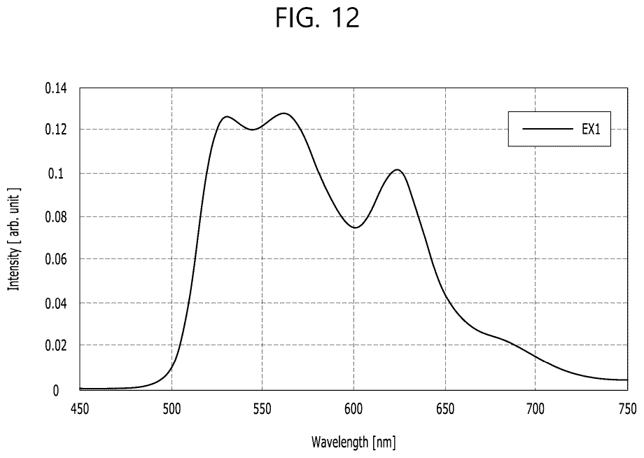

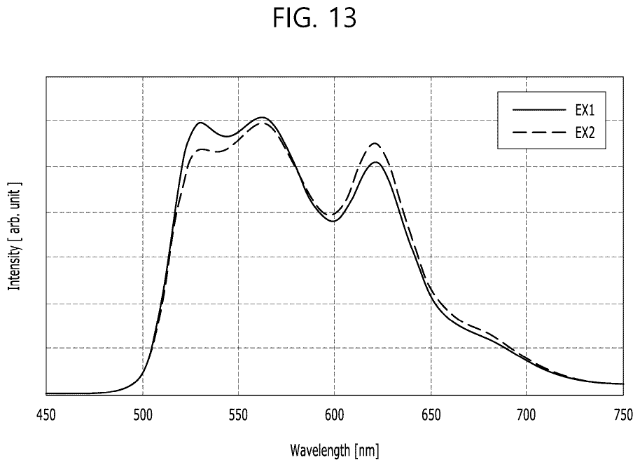

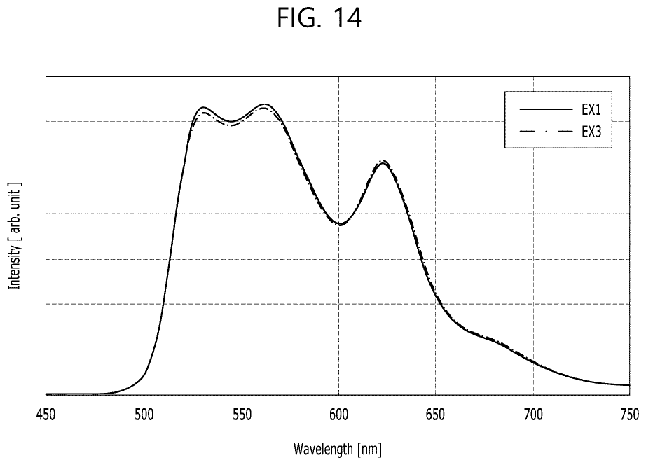

FIG. 12 is a graph showing an EL white light emitting spectrum of a tandem light emitting device including a phosphorescent light emitting layer of Experimental Example 1. FIG. 13 is a graph showing an EL white light emitting spectrum of a tandem light emitting device including a phosphorescent light emitting layer of Experimental Example 2. FIG. 14 is a graph showing an EL white light emitting spectrum of a tandem light emitting device including a phosphorescent light emitting layer of Experimental Example 3.

Compared to the third phosphorescent light emitting layer GEML provided with a hole-transporting host GHH and an electron-transporting host GEH as host materials, as shown in FIG. 12, the third phosphorescent light emitting layer GEML provided with a hole-transporting host GHH and an auxiliary exciton-forming host NGEH1 as host materials exhibit an increased efficiency at a red wavelength, but a decreased efficiency at a green wavelength, as shown in FIG. 13.

As shown in FIG. 14, when the host material of the third phosphorescent light emitting layer GEML is provided with an auxiliary exciton-forming host NGEH1 in addition to the hole-transporting host GHH and the electron-transporting host GEH, a white spectrum almost the same as in Experimental Example 1 (EX1) is obtained. In particular, when the third phosphorescent light emitting layer GEML includes an auxiliary exciton-forming host in addition to the electron-transporting host, both an auxiliary exciton-forming host NGEH1 that forms hetero-excitons and an electron-type host GEH that does not form hetero-excitons are used, the speed of electron movement is controlled to uniformly distribute charges between the first to third phosphorescent light emitting layers REML, YGEML, and GEML, thereby preventing excitons from being trapped at the interface between the light emitting layers, and providing uniform efficiency of color of emitted light and improved lifespan.

For example, it can be seen from the electro-optical characteristics of Table 1 and FIG. 14 that the light emitting device according to some embodiments of the present disclosure includes a combination of a hole-transporting host, an electron-transporting host, and an auxiliary exciton-forming host in the third phosphorescent light emitting layer, thereby providing efficiency comparable to Experimental Example 1 (EX1), and improved lifespan in each of the continuous phosphorescent layers. This demonstrates the importance of the structure.

An auxiliary host for forming auxiliary excitons is further formed in the phosphorescent light emitting layer, so that the additionally generated excitons can be used for light emission, the extinction of excitons in the light emitting layer can be reduced, and both luminous efficacy and lifespan can be improved.

An auxiliary exciton formation region is provided in the phosphorescent light emitting layer adjacent to the electron transport layer in the structure that includes a plurality of phosphorescent light emitting layers in succession, to control the movement speed of electrons, to distribute excitons throughout the phosphorescent light emitting layers and to improve white light emission efficiency.

The auxiliary exciton-forming host in addition to the dopant has a band gap energy to facilitate exciton acceptance, thereby distributing the excitons to areas other than the dopant, and improving both efficiency and lifespan.

The light emitting device and the light emitting display device including the same according to the present disclosure adopt certain materials for the light emitting layer, thereby improving luminous efficacy, reducing driving voltage, power consumption and thus environmental pollution, and realizing sustainable long-term lifespan and ESG (environmental/social/governance).

In addition, the light emitting device according to the present disclosure is a high-luminance white light emitting device that further includes an electron-type host to provide auxiliary exciton recombination in the green light emitting layer in the phosphorescent light emitting stack, and has the predetermined difference from the HOMO energy level of the hole-transporting host, to distribute excitons excessively concentrated in the green dopant into the auxiliary exciton-forming host, and improve the lifespan of the green light emitting layer while maintaining high efficiency. As a result, the trade-off relationship between lifespan and efficiency can be overcome.

Meanwhile, in the above-described embodiments, an example in which an auxiliary exciton-forming host is provided in the third phosphorescent light emitting layer GEML 145 is described. However, in some cases, the auxiliary exciton-forming host is also provided in the first phosphorescent light emitting layer 142 or the second phosphorescent light emitting layer 143. In this case, the phosphorescent light emitting layer includes a hole-transporting host and an electron-transporting host along with the auxiliary exciton-forming host, and the auxiliary exciton-forming host is designed to have a LUMO energy level which differs 2.4 eV to 2.7 eV from the HOMO energy level of the hole-transporting host in the phosphorescent light emitting layer, to achieve the effects described above.

Hereinafter, a light emitting display device to which the light emitting device of the present disclosure is applied will be described.

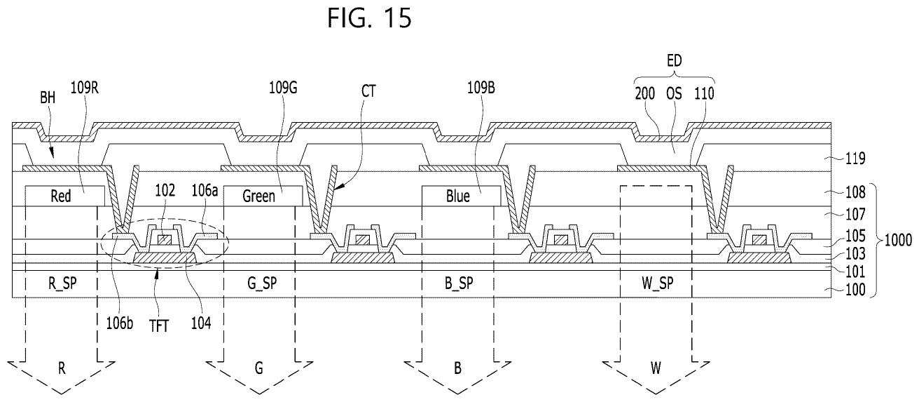

FIG. 15 is a cross-sectional view illustrating the light emitting display device according to some embodiments.

As shown in FIG. 15, the light emitting display device according to some embodiments can emit white light through the first electrode 110 in the light emitting area by commonly applying the light emitting device to a plurality of subpixels (R_SP, G_SP, B_SP, W_SP).

As shown in FIG. 15, the light emitting display of the present disclosure includes a substrate 100 having a plurality of subpixels R_SP, G_SP, B_SP, and W_SP, a light emitting device (also referred to as “ED”) commonly provided on the substrate 100, a thin film transistor TFT provided in each of the subpixels R_SP, G_SP, B_SP, and W_SP and connected to the first electrode 110 of the light emitting device ED, and a color filter layer 109R, 109G, or 109B provided below the first electrode 110 of at least one of the subpixels.

The example illustrated in FIG. 15 relates to a configuration including the white subpixel W_SP in the light emitting display device, but the present disclosure is not limited thereto. A configuration in which the white subpixel W_SP is omitted and only the red, green, and blue subpixels R_SP, G_SP, and B_SP are provided is also possible. In some cases, a combination of a cyan subpixel, a magenta subpixel, and a yellow subpixel capable of forming white by replacing the red, green, and blue subpixels is possible.

The thin film transistor TFT includes, for example, a gate electrode 102, a semiconductor layer 104, and a source electrode 106a and a drain electrode 106b connected to respective sides of the semiconductor layer 104. In addition, a channel protection layer can be further provided in the portion where the channel of the semiconductor layer 104 is located in order to prevent direct connection between the source/drain electrodes 106a and 106b and the semiconductor layer 104. The thin film transistor TFT can include a buffer layer 101 on the substrate 100 and can be located on the buffer layer 101.

A gate insulating layer 103 is provided between the gate electrode 102 and the semiconductor layer 104.

The semiconductor layer 104 can be formed of, for example, an oxide semiconductor, amorphous silicon, polycrystalline silicon, or a combination thereof. For example, when the semiconductor layer 104 is an oxide semiconductor, the heating temperature required for forming the thin film transistor can be lowered, and thus the substrate 100 can be freely used and the semiconductor layer 104 is advantageously applied to a flexible display device.

A gate electrode 102 can be provided on the gate insulating film 103, and an interlayer insulating film 105 can be further provided between the gate electrode 102 and the source electrode 106a/drain electrode 106b.

In addition, the drain electrode 106b of the thin film transistor TFT can be connected to the first electrode 110 in a contact hole CT provided in the first and second passivation layers 107 and 108.

The first passivation layer 107 is provided to primarily protect the thin film transistor TFT, and color filters 109R, 109G, and 109B can be provided on the first passivation layer 107.

A second passivation layer 108 is provided on the first passivation layer 107 including the color filters 109R, 109G, and 109B.

As shown in FIG. 15, when the plurality of subpixels includes a red subpixel R_SP, a green subpixel G_SP, a blue subpixel B_SP, and a white subpixel W_SP, the color filter can include first to third color filters 109R, 109G, and 109B in each of the remaining subpixels R_SP, G_SP, and B_SP, excluding the white subpixel W_SP, and can allow the emitted white light to pass through the first electrode 110 for each wavelength. A second passivation layer 108 is formed under the first electrode 110 to cover the first to third color filters 109R, 109G, and 109B. The first electrode 110 is formed on the surface of the second passivation layer 108 excluding the contact hole CT, is connected to either the drain electrode 106b or the source electrode 106a of the thin film transistor TFT and receives an electrical signal from the thin film transistor TFT.

Here, a configuration including the substrate 100, the thin film transistor TFT, the color filters 109R, 109G, and 109B, and the first and second protective films 107 and 108 can be defined as the thin film transistor array substrate 1000.

The light emitting device ED is formed on the thin film transistor array substrate 1000 including the bank 119 defining the light emitting portion BH. The light emitting device ED includes a transparent first electrode 110, a second electrode 200 of a reflective electrode facing the first electrode 110, and at least one of the first and second blue stacks B1 and B2 among the stacks separated through the first and second charge generation layers CGL1 and CGL2, including a hole transport layer HTL, an electron blocking layer EBL, and an energy transfer layer, a blue light emitting layer B EML containing a host BH and a blue dopant BD, and an electron transport layer ETL, between the first and second electrodes 110 and 200, as described above.

The first electrode 110 is divided into respective subpixels, and the remaining layers of the light emitting device ED excluding the first electrode 110 are integrally provided in the entire display area, regardless of respective subpixels.

Either the first electrode 110 or the second electrode 300 can be connected to a thin film transistor TFT.

When the light emitting display device of the present disclosure described above includes a blue stack including an electron blocking layer and a light emitting layer, the efficiency of blue, which has low efficiency compared to other colors, is improved, and in the light emitting device ED that emits white light maintains the balance between the phosphorescent light emitting stack and luminous efficacy, thereby greatly contributing to power consumption reduction.

A light emitting device according to some embodiments of the present disclosure can comprise a first electrode and a second electrode facing each other, and an intermediate layer having at least one blue light emitting stack and at least one phosphorescent light emitting stack between the first electrode and the second electrode, the intermediate layer emitting white light. The phosphorescent light emitting stack can comprise a first phosphorescent light emitting layer, a second phosphorescent light emitting layer, and a third phosphorescent light emitting layer, each emitting light with a longer wavelength than blue light. The third phosphorescent light emitting layer can comprise a hole-transporting host, an electron-transporting host, an auxiliary exciton-forming host having a LUMO energy level that is 2.4 eV to 2.7 eV different from a HOMO energy level of the hole-transporting host, and a dopant.

In a light emitting device according to some embodiments of the present disclosure, the auxiliary exciton-forming host can have a higher electron mobility than the hole-transporting host.

In a light emitting device according to some embodiments of the present disclosure, the LUMO energy level of the auxiliary exciton-forming host can be less than or equal to the LUMO energy level of the electron-transporting host.

In a light emitting device according to some embodiments of the present disclosure, a content of the hole-transporting host in the third phosphorescent light emitting layer can be greater than a total content of the electron-transporting host and the auxiliary exciton-forming host.

In a light emitting device according to some embodiments of the present disclosure, a content of the electron-transporting host can be approximately same as a content of the auxiliary exciton-forming host in the third phosphorescent light emitting layer.

In a light emitting device according to some embodiments of the present disclosure, a HOMO energy level of the auxiliary exciton-forming host can be lower than a HOMO energy level of the hole-transporting host, a LUMO energy level of the auxiliary exciton-forming host can be lower than a LUMO energy level of the hole-transporting host, and a band gap energy of the auxiliary exciton-forming host can be smaller than a band gap energy of the hole-transporting host.

In a light emitting device according to some embodiments of the present disclosure, the first phosphorescent light emitting layer, the second phosphorescent light emitting layer, and the third phosphorescent light emitting layer can be sequentially disposed on the first electrode and gradually emit short wavelength light while sequentially moving away from the first electrode.

In a light emitting device according to some embodiments of the present disclosure, among the first to third phosphorescent light emitting layers, the third phosphorescent light emitting layer can be the thickest and the second phosphorescent light emitting layer can be the thinnest.

In a light emitting device according to some embodiments of the present disclosure, a thickness of the third phosphorescent light emitting layer can be 250 Å to 350 Å. A thickness of the second phosphorescent light emitting layer can be half or less of the thickness of the third phosphorescent light emitting layer.

In a light emitting device according to some embodiments of the present disclosure, the first phosphorescent light emitting layer can a red light emitting layer, the second phosphorescent light emitting layer can be a yellow-green light emitting layer, and the third phosphorescent light emitting layer can be a green light emitting layer.

In a light emitting device according to some embodiments of the present disclosure, the first phosphorescent light emitting layer can contain the electron-transporting host in an amount greater than the hole-transporting host, and the second phosphorescent light emitting layer can contain the hole-transporting host in an amount equal to or greater than the electron-transporting host.

In a light emitting device according to some embodiments of the present disclosure, the auxiliary exciton-forming host of the third phosphorescent light emitting layer can be different from hosts contained in the first and second phosphorescent light emitting layers.

In a light emitting device according to some embodiments of the present disclosure, the first phosphorescent light emitting layer can be located between a hole transport layer and the second phosphorescent light emitting layer. The third phosphorescent light emitting layer can be disposed between the second phosphorescent light emitting layer and an electron transport layer. Also, a surface of the second phosphorescent light emitting layer can contact a surface of the first phosphorescent light emitting layer and the other surface of the second phosphorescent light emitting layer contacts the third phosphorescent light emitting layer.

A light emitting device according to of the present disclosure can further comprise a charge generation layer between the at least one blue light emitting stack and the at least one phosphorescent light emitting stack.

In a light emitting device according to some embodiments of the present disclosure, the first electrode can be a transparent electrode and the second electrode can include a reflective electrode.

A light emitting display device according to some embodiments of the present disclosure can comprise a substrate including a plurality of subpixels, a thin film transistor provided in each of the plurality of subpixels and a light emitting device connected to the thin film transistor and including a first electrode and a second electrode facing each other and an intermediate layer having at least one blue light emitting stack and at least one phosphorescent light emitting stack between the first electrode and the second electrode, the intermediate layer emitting white light.

A light emitting display device according to some embodiments of the present disclosure can further comprise a color filter between the substrate and the light emitting device in at least one of the subpixels.

The light emitting device and the light emitting display according to the present disclosure have the following effects.

The phosphorescent light emitting layer further includes an auxiliary host for forming auxiliary excitons, thus enabling the additionally generated excitons to be used for light emission, reducing the extinction of exciton component in the light emitting layer, and improving luminous efficacy and lifespan.

An auxiliary exciton-forming area is provided in the phosphorescent light emitting layer adjacent to the electron transport layer in the structure including a plurality of phosphorescent light emitting layers in succession, thereby controlling the movement speed of electrons, distributing excitons throughout the phosphorescent light emitting layers and improving white light emission efficiency.

The band gap energy of the auxiliary exciton-forming host is set to facilitate exciton acceptance in the auxiliary exciton-forming host in addition to the dopant, thereby distributing the excitons into areas other than the dopant and improving both efficiency and lifespan.

By changing the materials for the light emitting layers, the light emitting device according to the present disclosure and the light emitting display device including the same are capable of improving luminous efficacy, reducing driving voltage, power consumption and environmental pollution, providing sustainable effects of increasing lifespan, and realizing ESG (environmental/social/governance).

It will be apparent to those skilled in the art that various modifications and variations can be made in the disclosure without departing from the spirit or scope of the disclosure. Thus, it is intended that the disclosure covers such modifications and variations thereof, provided they fall within the scope of the appended claims and their equivalents.

What is claimed is:

1. A light emitting device comprising:
a first electrode and a second electrode facing each other, and
an intermediate layer having at least one blue light emitting stack and at least one phosphorescent light emitting stack between the first electrode and the second electrode, the intermediate layer configured to emit white light,
wherein the phosphorescent light emitting stack comprises a first phosphorescent light emitting layer, a second phosphorescent light emitting layer, and a third phosphorescent light emitting layer, each configured to emit light with a longer wavelength than blue light, and
wherein the third phosphorescent light emitting layer comprises a hole-transporting host, an electron-transporting host, an auxiliary exciton-forming host having a lowest unoccupied molecular orbital (LUMO) energy level that is 2.4 eV to 2.7 eV different from a highest occupied molecular orbital (HOMO) energy level of the hole-transporting host, and a dopant.

2. The light emitting device according to claim 1, wherein the auxiliary exciton-forming host has a higher electron mobility than the hole-transporting host.

3. The light emitting device according to claim 1, wherein the LUMO energy level of the auxiliary exciton-forming host is less than or equal to the LUMO energy level of the electron-transporting host.

4. The light emitting device according to claim 1, wherein a content of the hole-transporting host in the third phosphorescent light emitting layer is greater than a total content of the electron-transporting host and the auxiliary exciton-forming host.

5. The light emitting device according to claim 1, wherein a content of the electron-transporting host is approximately same as a content of the auxiliary exciton-forming host in the third phosphorescent light emitting layer.

6. The light emitting device according to claim 1, wherein:
a HOMO energy level of the auxiliary exciton-forming host is lower than a HOMO energy level of the hole-transporting host,
a LUMO energy level of the auxiliary exciton-forming host is lower than a LUMO energy level of the hole-transporting host, and
a band gap energy of the auxiliary exciton-forming host is smaller than a band gap energy of the hole-transporting host.

7. The light emitting device according to claim 1, wherein the first phosphorescent light emitting layer, the second phosphorescent light emitting layer, and the third phosphorescent light emitting layer are sequentially disposed on the first electrode and gradually emit short wavelength light while sequentially moving away from the first electrode.

8. The light emitting device according to claim 7, wherein, among the first to third phosphorescent light emitting layers, the third phosphorescent light emitting layer is the thickest and the second phosphorescent light emitting layer is the thinnest.

9. The light emitting device according to claim 1, wherein:
a thickness of the third phosphorescent light emitting layer is from 250 Å to 350 Å, and
a thickness of the second phosphorescent light emitting layer is half or less of the thickness of the third phosphorescent light emitting layer.

10. The light emitting device according to claim 1, wherein:
the first phosphorescent light emitting layer is a red light emitting layer,
the second phosphorescent light emitting layer is a yellow-green light emitting layer, and
the third phosphorescent light emitting layer is a green light emitting layer.

11. The light emitting device according to claim 7, wherein:
the first phosphorescent light emitting layer contains the electron-transporting host in an amount greater than the hole-transporting host, and
the second phosphorescent light emitting layer contains the hole-transporting host in an amount equal to or greater than the electron-transporting host.

12. The light emitting device according to claim 1, wherein the auxiliary exciton-forming host of the third phosphorescent light emitting layer is different from hosts contained in the first and second phosphorescent light emitting layers.

13. The light emitting device according to claim 1, wherein:
the first phosphorescent light emitting layer is located between a hole transport layer and the second phosphorescent light emitting layer,
the third phosphorescent light emitting layer is disposed between the second phosphorescent light emitting layer and an electron transport layer, and
a surface of the second phosphorescent light emitting layer contacts a surface of the first phosphorescent light emitting layer and the other surface of the second phosphorescent light emitting layer contacts the third phosphorescent light emitting layer.

14. The light emitting device according to claim 1, further comprising a charge generation layer between the at least one blue light emitting stack and the at least one phosphorescent light emitting stack.

15. The light emitting device according to claim 1, wherein the first electrode is a transparent electrode and the second electrode includes a reflective electrode.

16. A light emitting display device comprising:
a substrate including a plurality of subpixels;
a thin film transistor provided in each of the plurality of subpixels; and
a light emitting device connected to the thin film transistor and including a first electrode and a second electrode facing each other and an intermediate layer having at least one blue light emitting stack and at least one phosphorescent light emitting stack between the first electrode and the second electrode, the intermediate layer configured to emit white light,
wherein the phosphorescent light emitting stack comprises a first phosphorescent light emitting layer, a second phosphorescent light emitting layer, and a third phosphorescent light emitting layer, each configured to emit light with a longer wavelength than blue light, and
wherein the third phosphorescent light emitting layer comprises a hole-transporting host, an electron-transporting host, an auxiliary exciton-forming host having a lowest unoccupied molecular orbital (LUMO) energy level that is 2.4 eV to 2.7 eV different from a highest occupied molecular orbital (HOMO) energy level of the hole-transporting host, and a dopant.

17. The light emitting display device according to claim 16, further comprising a color filter between the substrate and the light emitting device in at least one of the plurality of subpixels.

18. The light emitting device according to claim 1, wherein the hole-transporting host comprises a material represented by Formula 2:

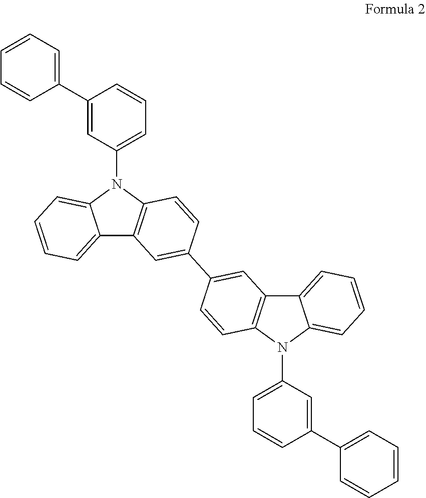 [SMILES: c1ccc(-c2cccc(-n3c4ccccc4c4cc(-c5ccc6c(c5)c5ccccc5n6-c5cccc(-c6ccccc6)c5)ccc43)c2)cc1]

19. The light emitting device according to claim 1, wherein the auxiliary exciton-forming host comprises a material represented by at least one of the following Formulas 4 to 7:

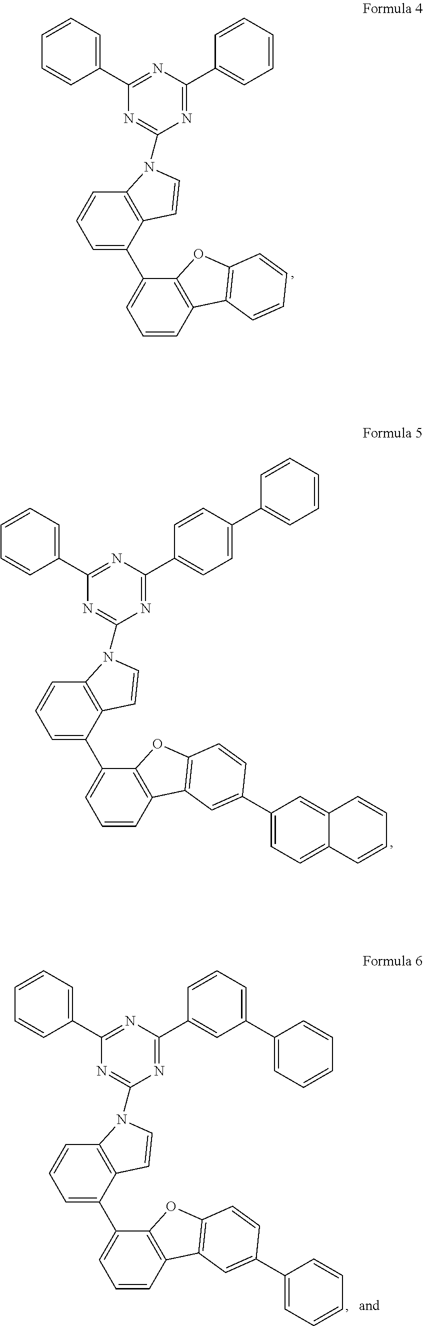 [SMILES: c1ccc(-c2nc(-c3ccccc3)nc(-n3ccc4c(-c5cccc6c5oc5ccccc56)cccc43)n2)cc1 ; c1ccc(-c2ccc(-c3nc(-c4ccccc4)nc(-n4ccc5c(-c6cccc7c6oc6ccc(-c8ccc9ccccc9c8)cc67)cccc54)n3)cc2)cc1 ; c1ccc(-c2cccc(-c3nc(-c4ccccc4)nc(-n4ccc5c(-c6cccc7c6oc6ccc(-c8ccccc8)cc67)cccc54)n3)c2)cc1]

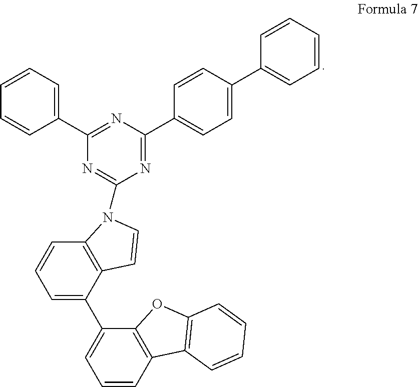 [SMILES: c1ccc(-c2ccc(-c3nc(-c4ccccc4)nc(-n4ccc5c(-c6cccc7c6oc6ccccc67)cccc54)n3)cc2)cc1]

20. A display device comprising: a display panel configured to display an image, and including a plurality of sub pixels,
wherein each of the plurality of sub pixels includes the light emitting device according to claim 1.
